(19) United States
(12) Patent Application Publication
(10) Pub. No.: US 2014/0084992 A1
(43) Pub. Date: Mar. 27, 2014

(54) TOUCH PANEL

(71) Applicants: Kuo-Hsing Chen, New Taipei City (TW); Yu-Ting Chen, Taoyuan County (TW); Chen-Hao Su, Taichung City (TW); Chin-Chang Liu, Taichung City (TW)

(72) Inventors: Kuo-Hsing Chen, New Taipei City (TW); Yu-Ting Chen, Taoyuan County (TW); Chen-Hao Su, Taichung City (TW); Chin-Chang Liu, Taichung City (TW)

(73) Assignees: WINTEK CORPORATION, Taichung City (TW); Wintek (China) Technology Ltd., Guangdong Province (CN)

(21) Appl. No.: 14/027,255

(22) Filed: Sep. 16, 2013

(30) Foreign Application Priority Data
Sep. 24, 2012 (TW) 101134919

(51) Int. Cl. H03K 17/96

(52) U.S. Cl. CPC H03K 17/9622
USPC 327/517; 200/5 A

(57) ABSTRACT

A touch panel includes a substrate, sensing electrode sets, first pads, second pads, first lines, second lines and connecting conductors. Each of the sensing electrode sets includes a first electrode pattern and a plurality of second electrode patterns disposed beside the first electrode pattern. The plurality of first lines electrically connects the first pads to the first electrode patterns respectively. Each second pad is electrically connected to one of the second electrode patterns through one of the second lines. Each connecting conductor electrically connects one second electrode pattern of one sensing electrode set to one second electrode pattern of another sensing electrode set. The first lines and the second lines do not cross over each other, and the connecting conductors do not cross over each other.

### CROSS-REFERENCE TO RELATED APPLICATION

This application claims the priority benefit of Taiwan application serial no. 101134919, filed on Sep. 24, 2012. The entirety of the above-mentioned patent application is hereby incorporated by reference herein and made a part of this specification.

### BACKGROUND OF THE INVENTION

1. Field of the Invention

The invention relates to a panel. More particularly, the invention relates to a touch panel.

2. Description of Related Art

FIG. 1 is a schematic top view of a part of a conventional projected capacitive touch panel having multi-layers of sensing electrodes. A projected capacitive touch panel 100 having multi-layers of sensing electrodes includes a substrate 110, a plurality of first sensing series 120, a plurality of second sensing series 130 and a plurality of lines 150. The lines 150 are respectively electrically connected to one first sensing series 120 or one second sensing series 130, and further connected to a control circuit 160, such as a control chip. Each of the first sensing series 120 includes a plurality of first electrode patterns 120a and each of the second sensing series 130 includes a plurality of second electrode patterns 130a. The first sensing series 120 and the second sensing series 130 cross over each other, and the touch panel 100 is configured with a plurality of bridge lines 140 and 142 for respectively connecting the first electrode patterns 120a and the second electrode patterns 130a. Accordingly, these sensing series are electrically independent from one another.

The touch panel 100 using the bridge lines 140 and 142 requires a complicate manufacturing process. In specific, the bridge lines 140 for connecting the first sensing patterns 120a in series and the bridge lines 142 for connecting the second electrode patterns 130a in series are formed by different conductive film layers and an insulation layer (not shown in FIG. 1) is disposed between the two. Therefore, for fabricating the required first sensing series 120 and the second series 130, contact windows need be formed in the insulation layer, or the insulation layer needs be patterned to make the bridge connection of the conductive components. Owing to the above reasons, the manufacturing method of the touch panel 100 is complicate and the cost thereof can not be reduced.

### SUMMARY OF THE INVENTION

The invention provides a touch panel capable of being manufactured by a simple method and having high yield.

The invention provides a touch panel including a substrate, a plurality of sensing electrode sets, a plurality of first pads, a plurality of second pads, a plurality of first lines, a plurality of second lines and a plurality of connecting conductors. The first pads and the second pads are disposed on the substrate. Each of the sensing electrode sets includes a first electrode pattern and a plurality of second electrode patterns disposed beside the first electrode pattern. The first lines respectively connect the first pads to the first electrode patterns. Each of the second pads is electrically connected to a corresponding second electrode pattern through one of the second lines, wherein the second lines and the first lines do not cross over each other. Each of the connecting conductors electrically connects one second electrode pattern of one sensing electrode set to one second electrode pattern of another sensing electrode set, wherein the connecting conductors do not cross over each other.

According to one embodiment of the invention, two terminals of each connecting conductor respectively connect to two of the second pads.

According to one embodiment of the invention, the connecting conductors includes a plurality of third lines disposed between the one second electrode pattern of the one sensing electrode set and the one second electrode pattern of the another sensing electrode set, such that the second electrode patterns in adjacent sensing electrode sets are electrically connected, in which the third lines, the first lines and the second lines do not cross over one another.

According to one embodiment of the invention, the first electrode patterns each has a first side and a second side opposite to the first side, and the second electrode patterns in the sensing electrode sets are located at the second sides of the corresponding first electrode patterns.

According to one embodiment of the invention, the first electrode pattern of each of the sensing electrode sets has a first side and a second side opposite to the first side, the second electrode patterns of a portion of the sensing electrode sets are located at the first sides of the corresponding first electrode patterns, and the second electrode patterns of another portion of the sensing electrode sets are located at the second sides of the corresponding first electrode patterns.

According to one embodiment of the invention, two first electrode patterns in two adjacent sending electrode sets are located between the second electrode patterns or the second electrode patterns in the two adjacent sensing electrode sets are located between the two first electrode patterns.

According to one embodiment of the invention, the first electrode pattern of each of the sensing electrode sets has a bend pattern to define a plurality of U-shaped patterns and the U-shaped patterns substantially surround the second electrode patterns respectively.

According to one embodiment of the invention, the U-shaped patterns defined by two first electrode patterns of two adjacent sensing electrode sets are opposite to each other.

According to one embodiment of the invention, the second electrode patterns located in the two opposite U-shaped patterns defined by the two adjacent sensing electrode sets are connected to each other.

According to one embodiment of the invention, the touch panel further includes a circuit board connected to the first pads and the second pads and the circuit board has the connecting conductors.

According to one embodiment of the invention, the material of the first lines and the second lines includes a transparent conductive material, a metal material, a metal mesh material, or a combination of at least two of the above.

According to one embodiment of the invention, the first lines and the second lines are disposed in a coplanar configuration.

According to one embodiment of the invention, the material of the sensing electrode sets includes a transparent conductive material, a metal material, a metal mesh material, or a combination of at least two of the above.

According to one embodiment of the invention, the touch panel further includes a decoration layer configured at the periphery of the substrate.

In view of the above, the electrodes of the touch panel according to the invention are disposed in a coplanar configuration, and one of the second electrode patterns in one sensing electrode set is electrically connected to one of the second electrode patterns in another sensing electrode set by using a plurality of connecting conductors. Thereby, the manufacturing method of the touch panel can be simplified. In the case that the touch panel is connected to the driving chip through a flexible circuit board, one pad of the flexible circuit board can be electrically connected to at least two electrode patterns, which facilitates to reduce the amounts of the pads in the flexible circuit board and shorten the length of the flexible circuit board. In the case that the touch panel is directly connected with the driving chip, such as the chip on glass (COG) connection, the amounts of the channels in the driving chip can be effectively reduced. In addition, the lines and the connecting conductors in the touch panel do not cross over each other, such that no additional manufactured process is required to bridge the conductive components in the touch panel, which conduces to simplify the manufacturing method of the touch panel and reduce the manufacturing cost, and further conduces to improve the yield.

In order to make the aforementioned and other features and advantages of the invention more comprehensible, embodiments accompanying figures are described in detail below.

### BRIEF DESCRIPTION OF THE DRAWINGS

FIG. 1 is a schematic top view of a part of a conventional projected capacitive touch panel having multi-layers of sensing electrodes.

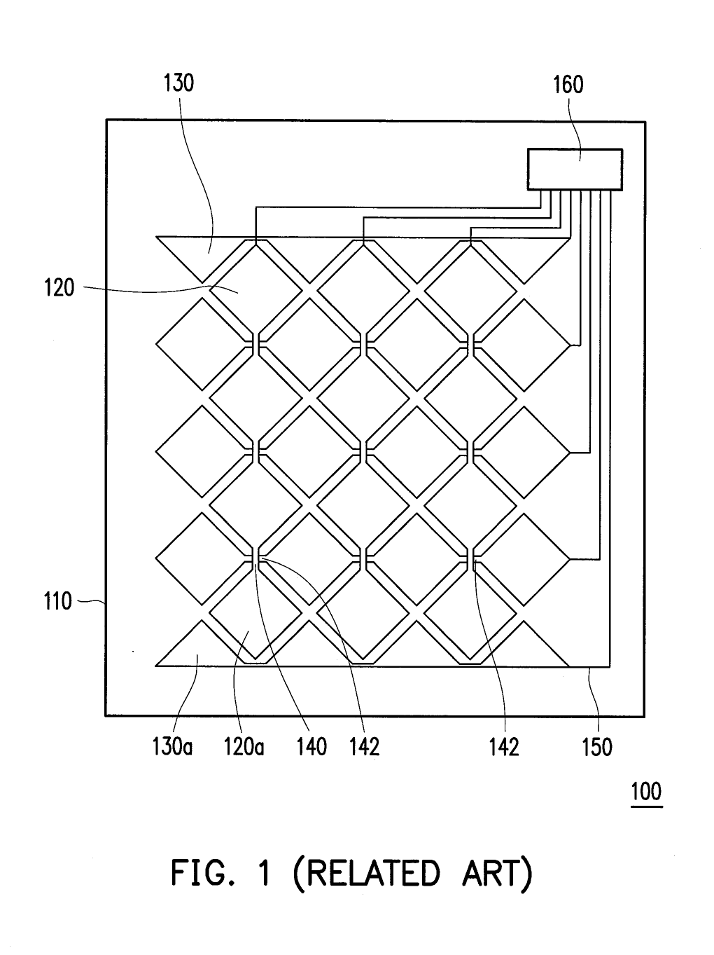

FIG. 2 is a schematic top view of a part of a touch panel according to the first embodiment of the invention.

FIG. 3A is a schematic top view of a part of a touch panel according to the second embodiment of the invention.

FIG. 3B is a schematic top view of a part of a touch panel according to the third embodiment of the invention.

FIG. 4 is a schematic top view of a part of a touch panel according to the fourth embodiment of the invention.

FIG. 5 is a schematic top view of a part of a touch panel according to the fifth embodiment of the invention.

FIG. 6 is a schematic top view of a part of a touch panel according to the sixth embodiment of the invention.

FIG. 7 is a schematic top view of a part of a touch panel according to the seventh embodiment of the invention.

FIG. 8 is a schematic top view of a part of a touch panel according to the eighth embodiment of the invention.

FIG. 9A is a schematic top view of a part of a touch panel according to the ninth embodiment of the invention.

FIG. 9B is a schematic top view of a part of a touch panel according to the tenth embodiment of the invention.

### DESCRIPTION OF EMBODIMENTS

The sizes of the components illustrated in the following drawings are modified so that the components can be clearly seen. Therefore, the sizes of the components in these drawings do not comply with the actual size thereof In addition, in the following descriptions of the embodiments, the amounts of the sensing electrode sets in one touch panel are schematically depicted, but the invention is not limited to the amounts thereof The designer can design the touch panel having the required amounts of the sensing electrode sets according to the factual consideration.

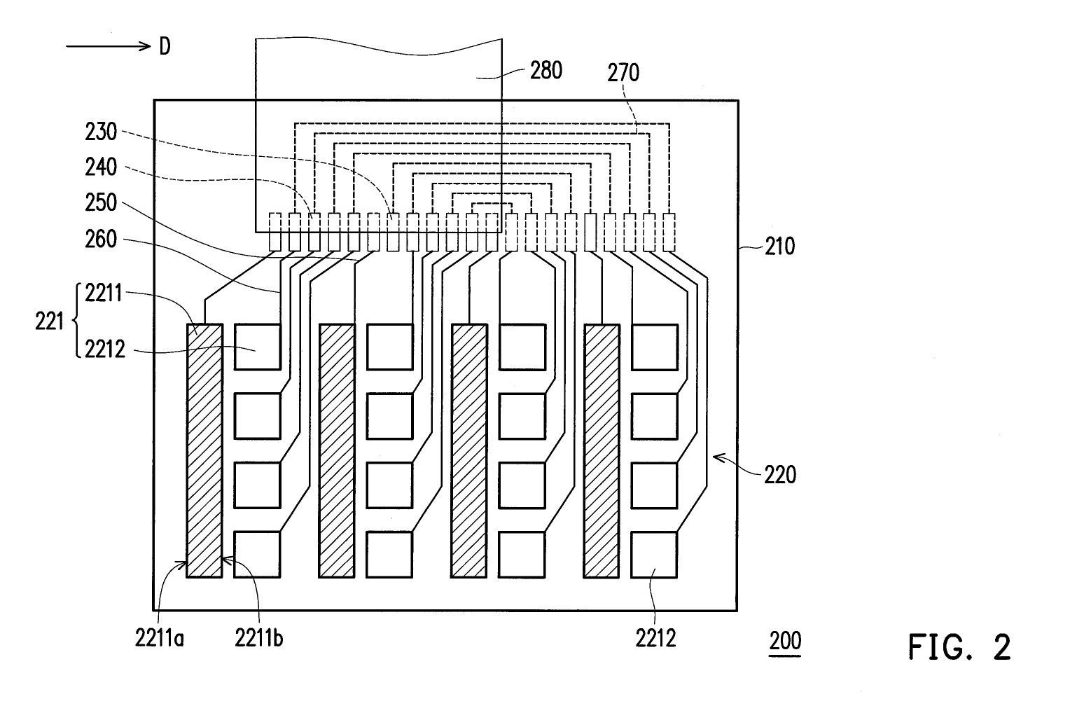

FIG. 2 is a schematic top view of a part of a touch panel according to the first embodiment of the invention. Referring to FIG. 2, a touch panel 200 includes a substrate 210, a sensing electrode layer 220, a plurality of first pads 230, a plurality of second pads 240, a plurality of first lines 250, a plurality of second lines 260 and a plurality of connecting conductors 270. The sensing electrode layer 220, the first pads 230 and the second pads 240 are disposed on the substrate 210. The sensing electrode layer 220 includes a plurality of sensing electrode sets 221 and each of the sensing electrode sets 221 includes a first electrode pattern 2111 and a plurality of second electrode patterns 2112 disposed beside the first electrode pattern 2111.

The plurality of first lines 250 respectively connects the first pads 230 to the first electrode patterns 2211. Furthermore, each of the second pads 240 is electrically connected to a corresponding second electrode pattern 2212 through one of the second lines 260. Each of the connecting conductors 270 electrically connects one second electrode pattern 2212 of one sensing electrode set 221 to one second electrode pattern 2212 of another sensing electrode set 221. It is noted that the second lines 260 and the first lines 250 do not cross over each other as shown in FIG. 2 and the connecting conductors 270 also do not cross over each other. The arrangements of the lines and the conductors can be achieved without a bridge connection so that the manufacturing method of the touch panel 200 can be simplified for further improving the yield. In other words, the first lines 250, the second lines 260 and the connecting conductors 270 can be selectively manufactured by using the same conductive film layer and thus no insulation layer is required to be disposed between the conductive components. Furthermore, the fabrication of contact windows in the insulation layer for achieving the required connection of the conductive components is omitted.

In the present embodiment, the first electrode pattern 2211 in each sensing electrode set 221 can be served as the scan electrode in the touch panel 200, and the second electrode patterns 2212 beside the first electrode pattern 2211 can be served as the receiving electrodes. The first electrode patterns 2211 of different sensing electrode sets 221 are scanned sequentially. In the case that the first electrode pattern 2211 in one sensing electrode set 221 is scanned, the corresponding second electrode patterns 2212 in the same sensing electrode set 221 can perform the sensing function. In specific, for example, touch panel 200 detects a capacitive effect by applying a pulse to each of first electrode pattern 2211 in turn, and then measuring a corresponding pulse from each of second electrode patterns 2212. Now, the signals sensed by the second electrode patterns 2212 can be transmitted to the corresponding second pad 240 through the corresponding second line 260 and output to the control chip (not shown) for generating a response command.

In order to ensure the signals sensed by the second electrode patterns 2212 in each sensing electrode set 221 to be separated, the plurality of second electrode patterns 2212 of the same sensing electrode set 221 are connected to different second pads 240. Nevertheless, the signals sensed by the second electrode patterns 2212 of different sensing electrode sets 221 can be separated by different scanning sequences, so that the second electrode patterns 2212 of the different sensing electrode sets 221 can selectively be connected to the same second pad 240. Accordingly, the control chip (not shown) can receive the signals sensed by at least two second electrode patterns 2212 in two sensing electrode sets 221 through one second pad 240, which facilitates to reduce the amounts of the pads configured on the flexible circuit board. In the case that the touch panel is directly connected with the driving chip, such as the chip on glass (COG) connection, the amounts of the channels in the driving chip can be effectively reduced.

Specifically, in the present embodiment, two terminals of each of the connecting conductors 270 are respectively connected to two of the second pads 240, so that one second electrode pattern 2212 in one of the sensing electrode sets 221 can be electrically connected to one second electrode pattern 2212 of another sensing electrode set 221. In other words, two of the second electrode patterns 221 belonging to different sensing electrode sets 221 can be electrically connected to different second pads 260 through different second lines 260. Furthermore, said two second pads 240 are electrically connected to each other through one corresponding connecting conductor 270, which achieves the connection that one second electrode pattern 2212 of one sensing electrode set 221 is electrically connected to one second electrode pattern 2212 of another sensing electrode set 221.

In the present embodiment, the touch panel 200 can further include a circuit board 280, which can be a flexible printed circuit board, for example. According to the electrical connection in the present embodiment, the amounts of the second pads 240 can be equivalent to the amounts of the second electrode patterns 2212. However, the circuit board 280 merely needs be in contact with all the first pads 230 and one of each two second pads 240 connected with the same connecting conductor 270 without in contact with all of the second pads 240 for transmitting the signals of the first electrode patterns 2211 and the second electrode patterns 2212 to the control chip (not shown) through the circuit board 280. In specific, only a half of the second pads 240 is required to be bonded to the circuit board 280 or the driving chip in the present embodiment. Through the above design, the circuit board can have a reduced size or the channel amounts of the driving chip can be reduced, which achieves the advantage of cost down. In other words, in the case that the touch panel 200 is configured with N second electrode patterns 2212, the circuit board 280 or the control chip (not shown) merely requires to be connected to N/2 second pads 240 for transmitting the signals sensed by the N second electrode patterns 2212 to accomplish the touch sensing function, wherein N is a positive integer.

In addition, the touch panel 200 according to the present embodiment has the electrode pattern design that the first electrode patterns 2211 and the second electrode patterns 2212 are disposed in the same plane to form a single layer of sensing electrode layer 220. In other words, the first electrode patterns 2211 and the second electrode patterns 2212 are manufactured by one same material film layer in the present embodiment, which renders the manufacturing method of the touch panel 200 simple. However, the invention does not limit the manufacturing method of the first electrode patterns 2211 and the second electrode patterns 2212. In one instance, the first electrode patterns 2211 and the second electrode patterns 2212 can be manufactured on the same plane respectively through different manufacturing processes. Furthermore, in the present embodiment, the first lines 250 and the second lines 260 can be disposed in a coplanar configuration, such that the first lines 250 and the second lines 260 can be manufactured in the same process, which simplifies the manufacturing method of the touch panel 200.

In the present embodiment, the material of the substrate 210 can be, for instance, glass, or plastic material while the material of the first pads 230, the second pads 240, the first lines 250 and the second lines 260 can be non-transparent conductive materials such as metal material (Cu) or metal mesh material, transparent conductive materials such as Indium Tin Oxide (ITO), or a combination of at least two of the above materials such as the composite material of ITO/Ag/ITO. The material of the sensing electrode layer 220 can be transparent conductive material such as Indium-Tin Oxide (ITO), other similar transparent conductive material, metal, metal mesh material, or a combination of at least two of the above materials such as the composite material of ITO/Ag/ITO. The above-listed materials are only exemplary and not intended to limit the present invention.

The dispositions, the functions, the electrical connections of the components in the first embodiment are described accompanying with the drawing and the arrangement of the sensing electrode sets 221 in the first embodiment is further described in the following with the drawing. Referring to FIG. 2 again, regarding the arrangement of the first electrode patterns 2211 and the second electrode patterns 2212 in the sensing electrode set 221 of the first embodiment, the first electrode patterns 2211 and the second electrode patterns 2212 are alternately arranged in the direction D. Specifically, the first electrode pattern 2211 of each of the sensing electrode sets 221 has a first side 2211a and a second side 2211b opposite to the first side 2211a, in which the first side 2211a and the second side 2211b can be represented as the left side and the right side in the drawing. The second electrode patterns 2212 of each sensing electrode set 221 are located at the second side 2211b of the corresponding first electrode pattern 2211. Namely, regarding to the drawing of FIG. 2, the second electrode patterns 2212 in each sensing electrode set 221 are located at the right side of the corresponding first electrode pattern 2211. Herein, the arrangements of the components in FIG. 2 are taken as an example of preferred embodiments, but have no intent to be construed as a limitation of the invention. For instance, in other embodiments, the second lines 260 can be located between the sensing electrode patterns 2211 and 2212 in the same sensing electrode set 221.

In the first embodiment, the first electrode patterns 2211 and the second electrode patterns 2212 are substantially arranged alternately in the first direction D. Under such design, besides the electrode patterns located at the most-left side in the drawing, the first side 2211a and the second side 2211b of each first electrode pattern 2211 are adjacent to a plurality of second electrode patterns 2212 in the touch panel 200. Alternately, a plurality of second electrode patterns 2212 is disposed between two adjacent first electrode patterns 2211.

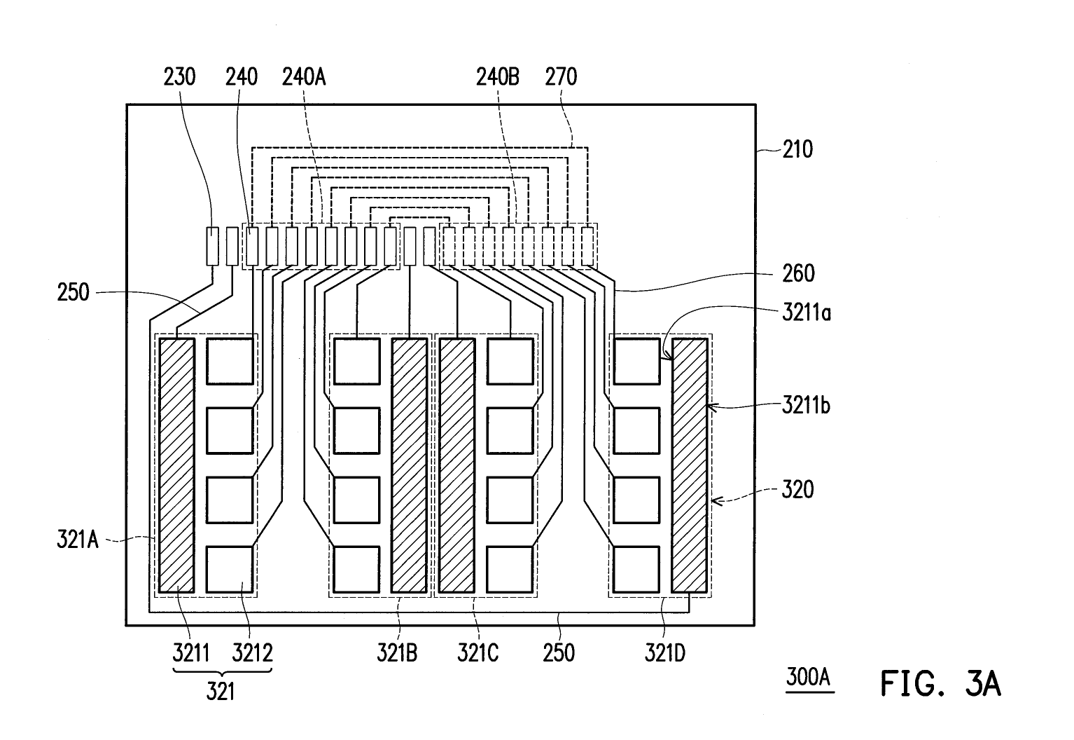

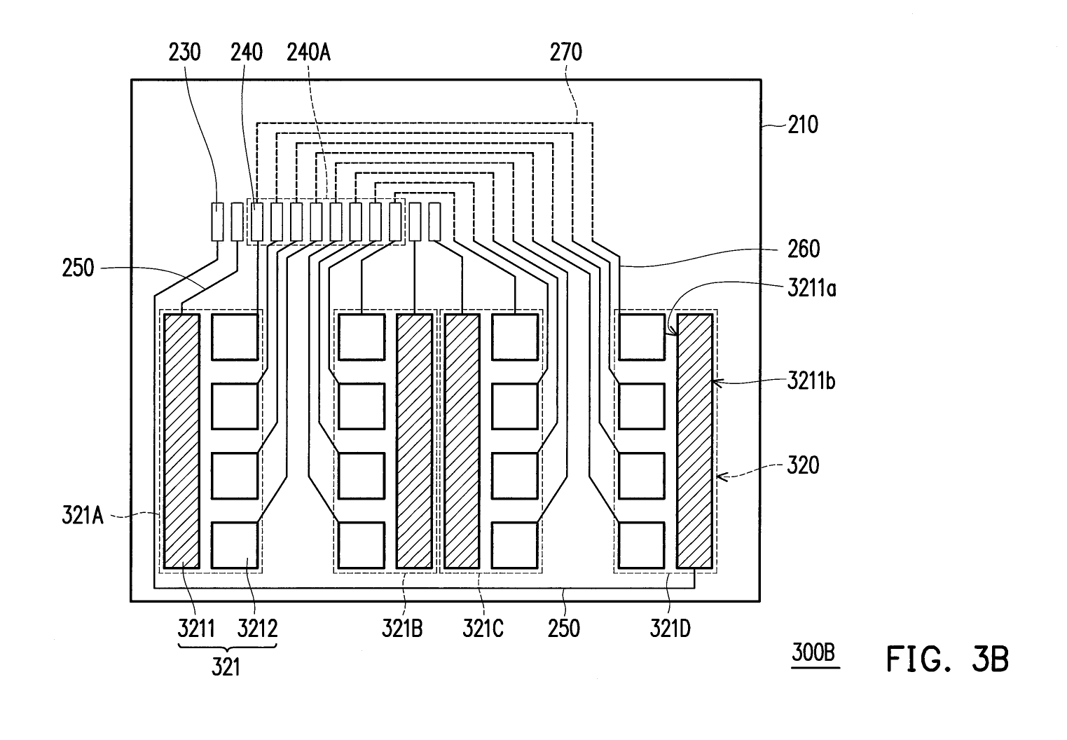

FIG. 3A is a schematic top view of a part of a touch panel according to the second embodiment of the invention. In the second embodiment, the dispositions of the components are similar to those of the first embodiment, such that the same or similar reference numerals or labels represent the same or similar components in the second and the first embodiment. The major difference between the second embodiment and the first embodiments is that the arrangements of the sensing electrode sets 321A˜321D in the sensing electrode layer 320 of the touch panel 300A. Nevertheless, other components in the second embodiment have similar design to the ones in the first embodiment. In other words, each first pad 230 is connected to the corresponding first electrode pattern 2211 through one first line 250 and each second pad 240 is connected to the corresponding second electrode pattern 2212 through one second line 260.

Referring to FIG. 3A, in the second embodiment, the first electrode pattern 3211 of each of the sensing electrode sets 321A˜321D has a first side 3211a and a second side 3211b opposite to the first side 3211a, the second electrode patterns 3212 of a portion of the sensing electrode sets 321 are located at the first sides 3211a of the corresponding first electrode patterns 3211, and the second electrode patterns 3212 of another portion of the sensing electrode sets 321 are located at the second sides 3211b of the corresponding first electrode patterns 3211.

Specifically, in the touch panel 300, the two first electrode patterns 3211 belonging to two adjacent sensing electrode sets 321, such as the sensing electrode set 321B and the sensing electrode set 321C, are located between the second electrode patterns 3212 or the second electrode patterns 3212 in two sensing electrode sets 321, such as the sensing electrode sets 321A and 321B or the sensing electrode sets 321C and 321D, are located between the corresponding two first electrode patterns 3211. As such, the arrangement of the sensing electrode sets 321A˜321D has a symmetric configuration.

In the present embodiment, the second electrode patterns 3212 of the sensing electrode sets 321A and 321B are adjacently arranged, such that the second pads 240 connected to the sensing electrode set 321A and the sensing electrode set 321B can be closely disposed at the first pad area 240A. Similarly, the second electrode patterns 3212 of the sensing electrode sets 321C and 321D are adjacently arranged, such that the second pads 240 connected to the sensing electrode set 321C and the sensing electrode set 321D can be closely disposed at the second pad area 240B. Herein, the second pads 240 in the second pad area 240B can be connected to the second pads 240 in the first pad area 240A through the connecting conductors 270. The control chip of the touch panel 300 or the circuit board for connecting the touch panel 300 to the control chip can be merely bonded to the second pads 240 in the first pad area 240A for electrically connecting to all the second electrode patterns 3212 to accomplish the transmission and the receiving of the touch sensing signals. Namely, the second pads 240 disposed in the second pad area 240B can be considered as dummy pads which are not physically connected to the control chip or the circuit board.

In the second embodiment, the arrangement of the electrode patterns includes that a portion of the first electrode patterns 3211 are neighboring to each other, such as the first electrode pattern 3211 of the sensing electrode set 321B and the first electrode pattern 3211 of the sensing electrode set 321C. Herein, the, first electrode pattern 3211 of the sensing electrode set 321C and the second electrode patterns 3212 of the sensing electrode set 321C are stayed in an initial state, such as in the grounding or floating state, when the first electrode pattern 3211 of the sensing electrode set 321B is scanning. Accordingly, the first electrode pattern 3211 of the sensing electrode set 321C can provide a shielding effect which prevents the second electrode pattern 3212 of the sensing electrode set 321C from sensing during the sensing period of the sensing electrode set 321B. In addition, the second electrode patterns 3212 of the sensing electrode set 321C can provide a noise shielding effect. Accordingly, the touch panel 300A has satisfactory touch sensing accuracy. Herein, it is taken as a descriptive example that the first electrode pattern 3211 of the sensing electrode set 321C and the second electrode patterns 3212 of the sensing electrode set 321C are stayed in the initial state when the first electrode pattern 3211 of the sensing electrode set 321B is scanning. In other embodiment, only one of the first electrode pattern 3211 and the second electrode patterns 3212 in the sensing electrode set 321C can be optionally stayed in the initial state.

FIG. 3B is a schematic top view of a part of a touch panel according to the third embodiment of the invention. In the second embodiment, the second pads 240 disposed in the first pad area 240A and the second pad area 240B are connected through the connecting conductors 270 so as to connect to the corresponding second electrode patterns 3212. Nevertheless, the second pad area 240B can be optionally not configured with the second pads 240 and the connecting conductors 270 can directly connect to the second lines 260 connected with the sensing electrode set 321C and the sensing electrode set 321D. Referring to FIG. 3B, the third embodiment of FIG. 3B and the second embodiment are substantially similar and the difference between the two mainly lies in that the second pad area 240B in the third embodiment is not configured with the second pads 240. The designer can selectively omit the disposition of the second pads 240 in the second pad area 240B.

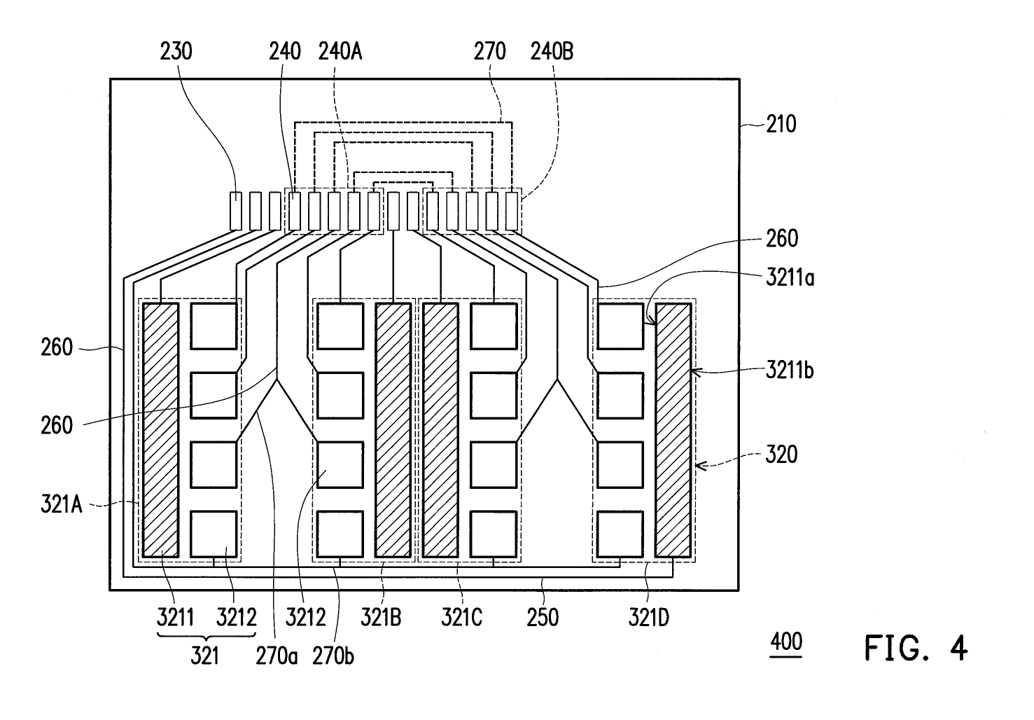

FIG. 4 is a schematic top view of a part of a touch panel according to the fourth embodiment of the invention. Referring to FIG. 4, in the fourth embodiment, the dispositions of the components and the arrangements of the sensing electrode sets 321A˜321D are similar to those of the second embodiment, such that the same or similar reference numerals or labels represent the same or similar components in the second and the fourth embodiments. The difference between the two mainly lies in that the touch panel 400 in the fourth embodiment further adopts a plurality of third lines 270a as the connecting conductors in addition to the connecting conductor 270 connected to two second pads 240. Thereby, the second electrode patterns 3212 of different sensing electrode sets 321 can be connected in another manner. In specific, each third line 270a is disposed between one second electrode pattern 3212 of one of the sensing electrode sets 321A˜321D and one second electrode pattern 3212 of another of the sensing electrode sets 321A˜321D, so that the second electrode patterns 3212 in adjacent sensing electrode sets 321A˜321D can be electrically connected with each other.

In the second embodiment, each of the second electrode patterns 3212 is connected to the second pad 240 through one corresponding second line 260. In the third embodiment, the third lines 270a can connect a portion of the second electrode patterns 3212 in the sensing electrode set 321A and the second electrode set 321B, and one second line 260 is used for electrically connecting the portion of the second electrode patterns 3212 in the sensing electrode set 321A and the second electrode set 321B to the second pad 240. Alternately, the third lines 270a can connect a portion of the second electrode patterns 3212 in the sensing electrode set 321C and the second electrode set 321D, and one second line 260 is used for electrically connecting the portion of the second electrode patterns 3212 in the sensing electrode set 321C and the second electrode set 321D to the second pad 240. Therefore, at least one of the second pads 240 can be electrically connected to the second electrode patterns 3212 in different sensing electrode sets 321A˜321D through one second line 260 and one third line 270a. Thereby, the amounts of the second lines 260 and the second pads 240 can be reduced.

In the present embodiment, the second electrode patterns 3212 located farther from the first pads 230 and the second pads 240 can be connected together through the same third line 270b. Now, the third line 270b simultaneously is connected to one second electrode pattern 3212 of each of the sensing electrode sets 321A˜321D, which is not similar to the line 270a connected to one second electrode pattern 3212 of each of the adjacent two sensing electrode sets 321A and 321B or the adjacent two sensing electrode sets 321C and 321D. Furthermore, a portion of the layout path of the third line 270b extending outwardly to connect to the second pad 240 can be served as the corresponding second line 260. That is to say, the third line 270b and the corresponding second line 260 can be formed as a continuous conductive line so as to connect with each other and the third line 270b and the second line 260 are defined by different parts of the continuous conductive line.

In addition, in the fourth embodiment, the third lines 270a, 270b, the first lines 250 and the second lines 260 do not cross over each other so that, similar to the above embodiments, no bridge manufacturing process is required for manufacturing the touch panel 400. Furthermore, the arrangement of the sensing electrode sets 321 in the fourth embodiment is similar to the second embodiment, which conduces to improve the sensing accuracy by the shielding effect of the non-scanned first electrode patterns 3211.

In the fourth embodiment, the first pad area 240A and the second pad area 240B are disposed with the second pads 240. However, in other embodiment, the second pad area 240B can be selectively not disposed with the second pads 240 and the connecting conductors 270 can be directly connected to the second lines 260 connected to the sensing electrode set 321C and the sensing electrode set 321D.

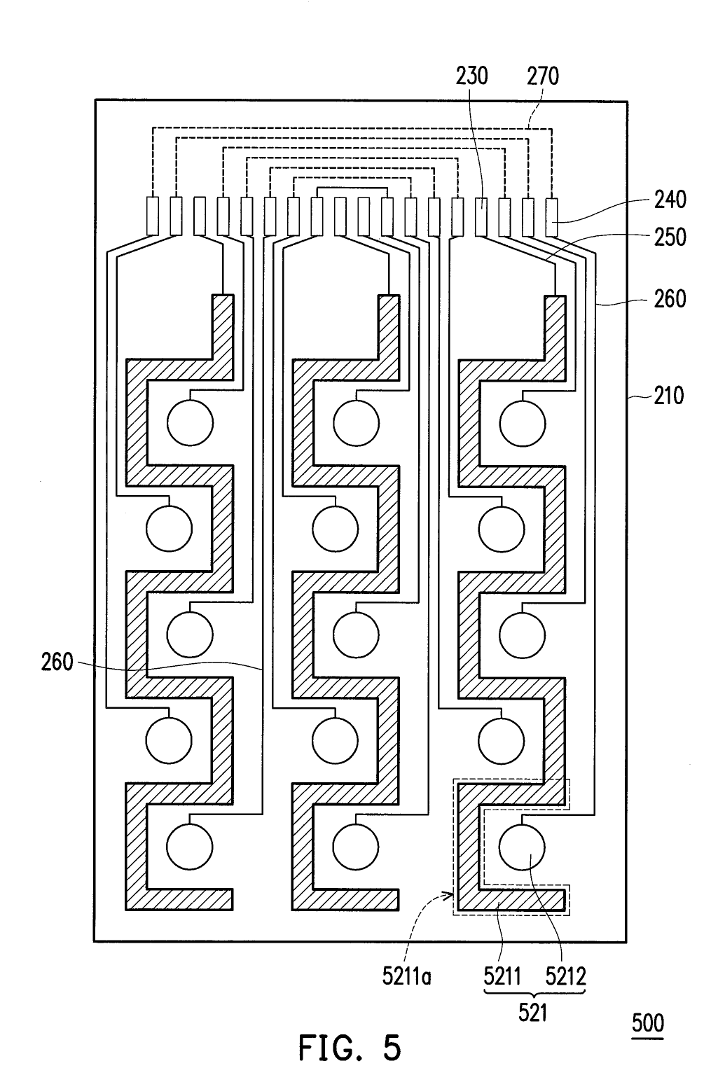

FIG. 5 is a schematic top view of a part of a touch panel according to the fifth embodiment of the invention. In the above first to fourth embodiments, the shapes of the first electrode patterns 2211 and 3211 are bar-like shapes, which are taken as examples, and the shapes of the first electrode patterns 2211 and 3211 are not limited. Referring to FIG. 5, a touch panel 500 includes a substrate 210, a plurality of sensing electrode sets 521, a plurality of first pads 230, a plurality of second pads 240, a plurality of first lines 250, a plurality of second lines 260 and a plurality of connecting conductors 270. The first electrode pattern 5211 in each sensing electrode set 521 has a bend shape defining a plurality of U-shaped pattern 5211a. Each of the U-shaped patterns 521a substantially surrounds one second electrode pattern 5212 belonging to the same sensing electrode set 521. In the fifth embodiment, the second electrode patterns 5212 are illustrated as circle patterns, but the invention is not limited thereto. The second electrode patterns 5212 can have other shapes capable of being surrounded by the U-shaped patterns 5211a, such as triangles, rectangles, hexagons, or the like.

In the present embodiment, each second electrode pattern 5212 is connected to one second pad 240 through one second line 260. Accordingly, without the connecting conductors 270, the control chip or the circuit board connected between the control chip and the touch panel 500 needs be connected to every second pad 240 for connecting the touch panel 500 to the control chip. Namely, the amount of the channels in the control chip or the pads of the circuit board has to be equal to the amount of the second electrode patterns 5212. As such, the bonding area of the control chip or the circuit board can not be reduced. The connecting conductors 270 in the present embodiment connect the second electrode patterns 5212 of different sensing electrode set 521 together. Now, the control chip or the circuit board connected between the control chip and the touch panel 500 is only connected to one of the second pads 240 connected with each connecting conductor 270. This layout method is conducive to reduce the bonding area of the circuit board. Once the COG connection is applied, the layout design is conducive to reduce the channel amounts of the control chip for simplify the design of the control chip.

In the present embodiment, a portion of the second pads 240 can be omitted and the connecting conductors 270 can be directly connected to the corresponding second lines 260.

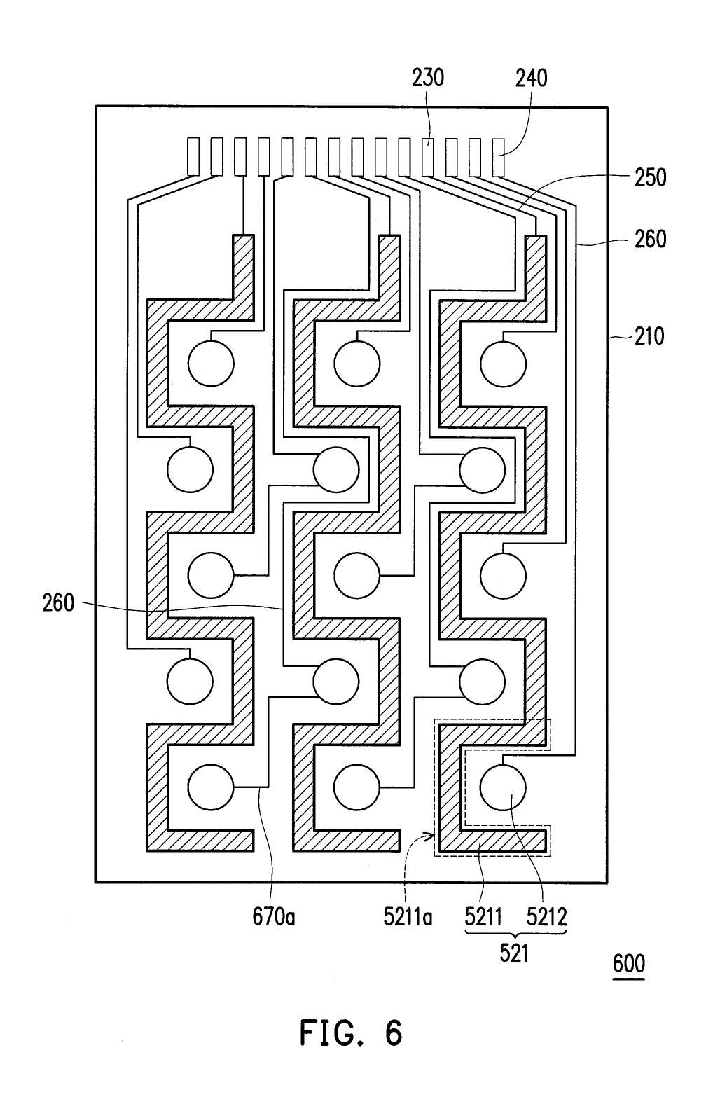

FIG. 6 is a schematic top view of a part of a touch panel according to the sixth embodiment of the invention. Referring to FIG. 6, the sixth embodiment is similar to the fifth embodiment, such that the same or similar reference numerals or labels represent the same or similar components. The difference between the two mainly lies in that the touch panel 600 of the sixth embodiment further includes a plurality of third lines 670a which electrically connect a portion of the second electrode patterns 5212 in adjacent sensing electrode sets 521. Furthermore, the second lines 260 make the connected second electrode patterns 5212 electrically connect to the corresponding second pads 240. Accordingly, the amount of the second lines 260 and the second pads 240 can be reduced, which simplify the manufacturing method of the touch panel 600 and reduce the manufacturing cost. The disposition of the third lines 670a is used for connecting the second electrode patterns 5212 in different sensing electrode sets 521, such that the same second pad 240 can connect to different second electrode patterns 5212.

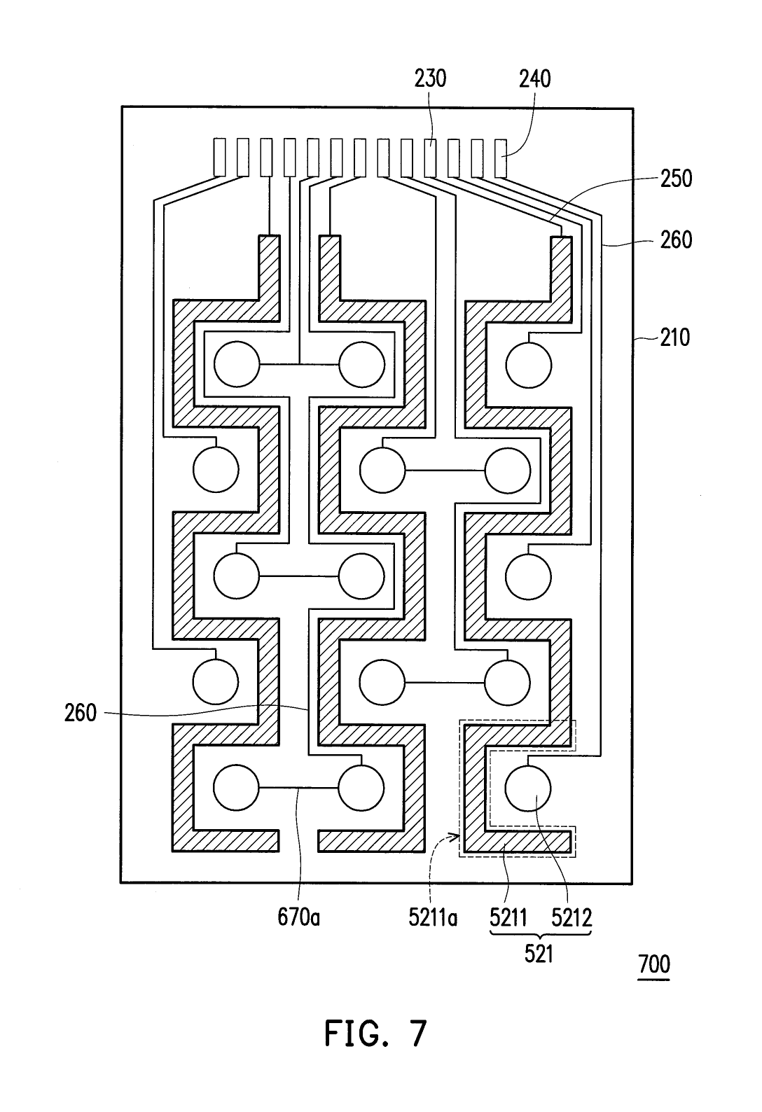

FIG. 7 is a schematic top view of a part of a touch panel according to the seventh embodiment of the invention. Referring to FIG. 7, the seventh embodiment is similar to the sixth embodiment, such that the same or similar reference numerals or labels represent the same or similar components. The difference between the two mainly lies in that the U-shaped patterns 5211a defined by two first electrode patterns 5211 of two adjacent sensing electrode sets 521 are opposite to each other in the touch panel 700 of the seventh embodiment. Therefore, the third lines 670a connected between the second electrode patterns 5212 in the two adjacent sensing electrode sets 521 can have a straight linear pattern, rather than the bend pattern shown in FIG. 6.

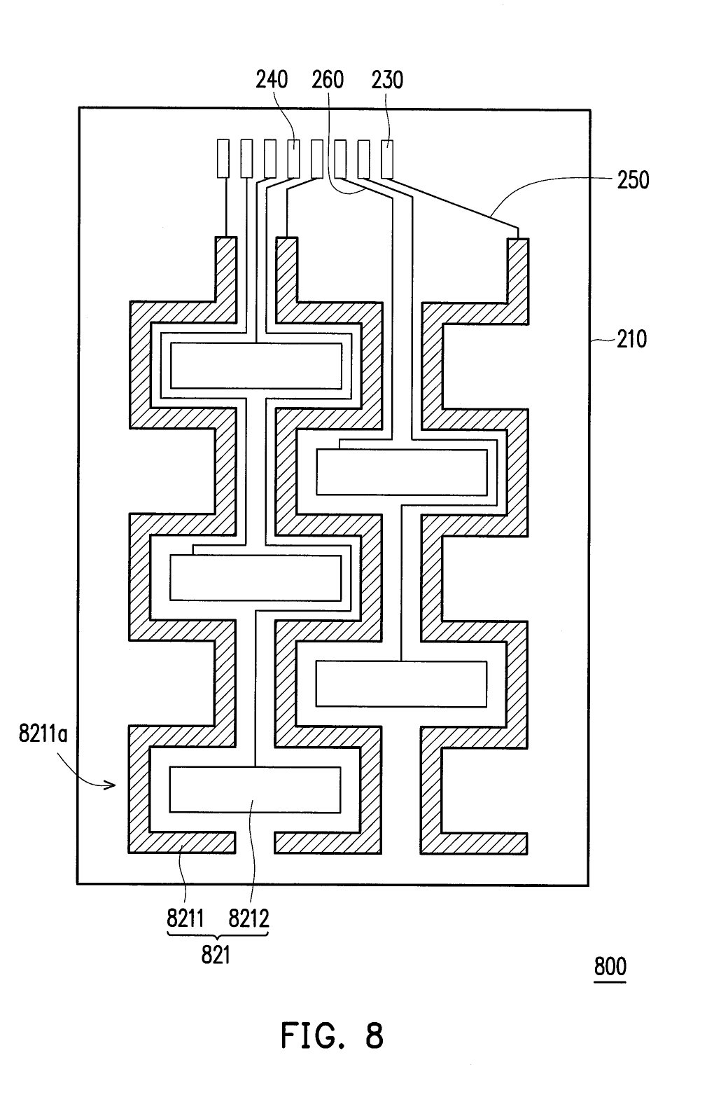

FIG. 8 is a schematic top view of a part of a touch panel according to the eighth embodiment of the invention. Referring to FIG. 8, the eighth embodiment is similar to the seventh embodiment, such that the same or similar reference numerals or labels represent the same or similar components. The difference between the two mainly lies in that the second electrode patterns 8212 located in the opposite U-shaped patterns 8211a defined by the two adjacent sensing electrode sets 821 are connected to each other.

Similar to the fifth to the eighth embodiments in above, a portion of the second pads 240 can be omitted and the connecting conductors 270 can be directly connected to the corresponding second lines 260. Most part of the embodiment is the same as that of the above embodiments, and it will not be repeated.

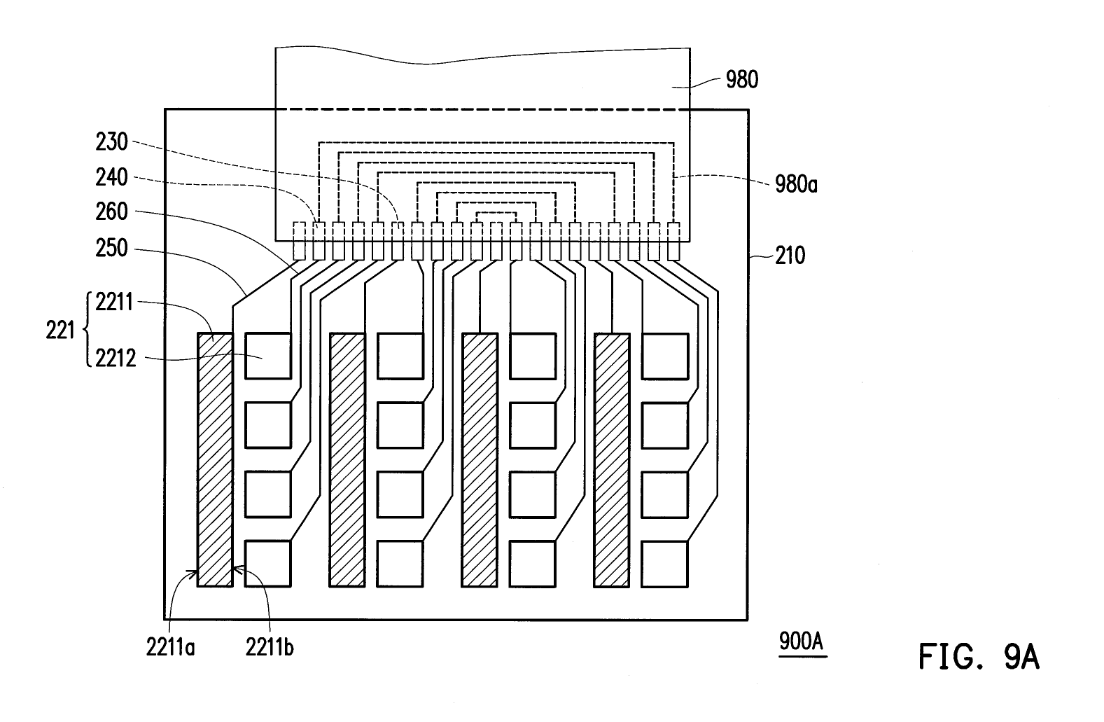

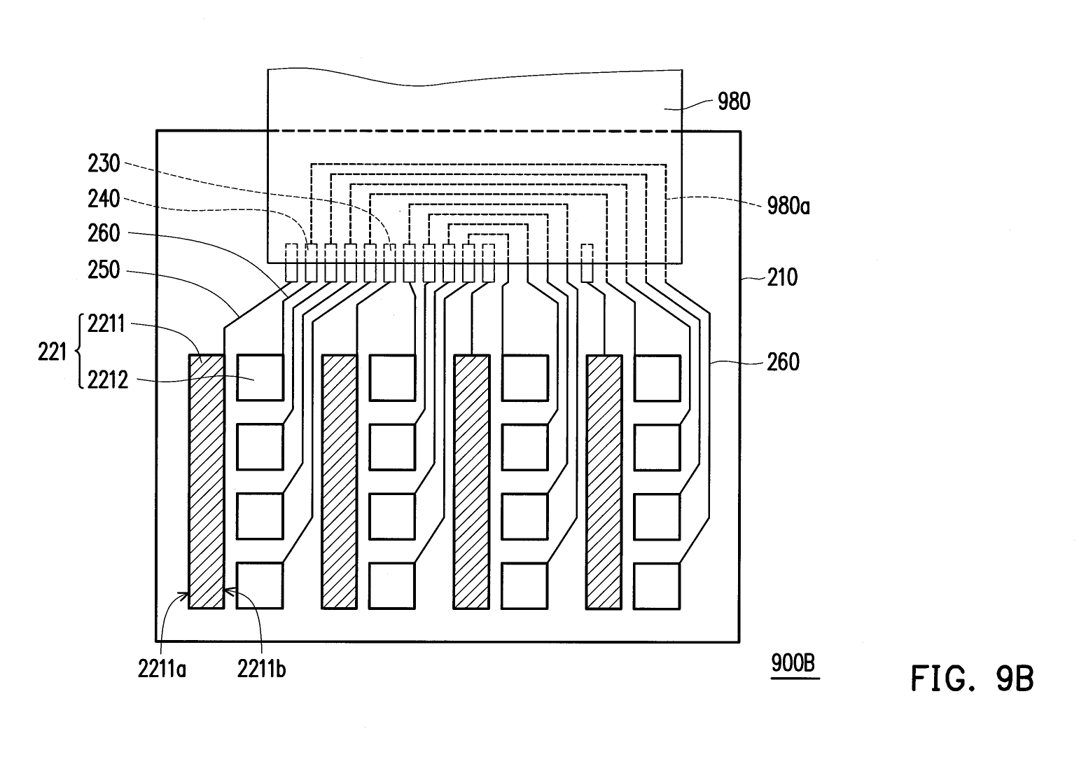

Note that the connecting conductors 270 connected with two second pads 240 as depicted in the first to the fourth embodiments are fabricated on the substrate 210, but the invention is not limited thereto. FIG. 9A is a schematic top view of a part of a touch panel according to the ninth embodiment of the invention. Referring to FIG. 9A, the ninth embodiment is similar to the first embodiment, such that the same or similar reference numerals or labels represent the same or similar components. The main difference between the two mainly lies in that the touch panel 900A in the ninth embodiment further includes a circuit board 980. The circuit board 980 is connected to the first pads 230 and the second pads 240 and has the connecting conductors 980a. In other words, the layout design of the circuit board 980 adopted in the present embodiment is used for connecting different second pads 240 together. Here, the substrate 210 of the touch panel 700 is configured with the conductive components not crossing over each other. Thereby, the manufacturing process for forming contact windows in an insulation layer or patterning the insulation layer is not needed for accomplishing the connection of the conductive components.

In one embodiment, the circuit board 980 can be a flexible printed circuit board and the connecting conductors 980a can be formed by using the wiring layers therein. In specific, the flexible printed circuit board can be bonded to the substrate 210 through an adhesive process or the like for connecting the wiring layers to the corresponding first pads 230 and the second pads 240, which facilitates to transmit the signals of the first electrode patterns 2211 and the second electrode patterns 2212 and reduce the required amounts of the channels for controlling the touch panel 900A. It is noted that the circuit board 980 can be a printed circuit board, in which the connecting conductors 980a can be formed by the conductive layers fabricated in the printed circuit board.

FIG. 9B is a schematic top view of a part of a touch panel according to the tenth embodiment of the invention. The tenth embodiment is similar to the ninth embodiment and the difference between the two lies in that a portion of the second pads 240 in the tenth embodiment is omitted and a portion of the second lines 260 can be directly connected to the corresponding connecting conductor 980a.

In addition, the connecting conductor 980a can be formed by the circuit design in the control chip. For example, the electrical connection of the first pads 230 and the second pads 240 can be achieved by the circuit design in the control chip, for the same channel processing the signals transmitted in two second pads 240. Here, the circuit in the control chip provides the function similar to the connecting conductors 980a.

Furthermore, in other embodiments, a decoration layer (not shown) can be disposed at the periphery of the substrate and the substrate can be a cover lens. For example, the decoration layer can include a material of at least one of ceramic material, diamond-like carbon, colored ink, photoresist, or resin material for shielding a portion of the first lines and/or the second lines located at the periphery of the substrate. In other embodiments, the substrate may be one of multiple substrates of a display. For example, the substrate may be a color filter substrate of the display, or an encapsulation cover of an organic light emitting diode display, but is not limited.

In light of the foregoing, the touch panel according to the invention adopts the connecting conductors connecting one second electrode pattern in one sensing electrode set to one second electrode pattern in another sensing electrode set. The connecting conductors can be connected to the corresponding second pads, or be formed as lines connecting the two corresponding second electrode patterns. The lines and the connecting conductors in the touch panel do not cross over each other, so that no bridge connection is required in the touch panel. Consequently, the touch panel of the invention facilitates to simplify the manufacturing method and improve the yield. In addition, in the touch panel according to the invention, the electrode patterns include a plurality of shapes and arrangements, which has great design flexibility.

Although the invention has been described with reference to the above embodiments, it will be apparent to one of the ordinary skill in the art that modifications to the described embodiment may be made without departing from the spirit of the invention. Accordingly, the scope of the invention will be defined by the attached claims not by the above detailed descriptions.

What is claimed is:

1. A touch panel, comprising:
a substrate;
a plurality of sensing electrode sets disposed on the substrate, wherein each of the sensing electrode sets comprises:
a first electrode pattern; and
a plurality of second electrode patterns disposed beside the first electrode pattern;
a plurality of first pads disposed on the substrate;
a plurality of second pads disposed on the substrate;
a plurality of first lines, respectively connecting the first pads to the first electrode patterns;
a plurality of second lines, each of the second pads being electrically connected to a corresponding second electrode pattern through one of the second lines, wherein the second lines and the first lines do not cross over each other; and
a plurality of connecting conductors, each of the connecting conductors electrically connecting one second electrode pattern of one sensing electrode set to one second electrode pattern of another sensing electrode set, wherein the connecting conductors do not cross over each other.

2. The touch panel as claimed in claim 1, wherein two terminals of each of the connecting conductors are respectively connected to two of the second pads.

3. The touch panel as claimed in claim 1, wherein the connecting conductors comprises a plurality of third lines disposed between the one second electrode pattern of the one sensing electrode set and the one second electrode pattern of the another sensing electrode set, such that the second electrode patterns in adjacent sensing electrode sets are electrically connected, in which the third lines, the first lines and the second lines do not cross over each other.

4. The touch panel as claimed in claim 1, wherein the first electrode pattern of each of the sensing electrode sets has a first side and a second side opposite to the first side, and the second electrode patterns of the sensing electrode sets are located at the second sides of the corresponding first electrode patterns.

5. The touch panel as claimed in claim 1, wherein the first electrode pattern of each of the sensing electrode sets has a first side and a second side opposite to the first side, the second electrode patterns of a portion of the sensing electrode sets are located at the first sides of the corresponding first electrode patterns, and the second electrode patterns of another portion of the sensing electrode sets are located at the second sides of the corresponding first electrode patterns.

6. The touch panel as claimed in claim 5, wherein the first electrode patterns of two adjacent sensing electrode sets are located between the second electrode patterns or the second electrode patterns of the two adjacent sensing electrode sets are located between the two first electrode patterns.

7. The touch panel as claimed in claim 1, wherein the first electrode pattern of each of the sensing electrode sets has a bend pattern to define a plurality of U-shaped patterns and the U-shaped patterns substantially surround the second electrode patterns respectively.

8. The touch panel as claimed in claim 7, wherein the U-shaped patterns defined by two first electrode patterns of two adjacent sensing electrode sets are opposite to each other.

9. The touch panel as claimed in claim 8, wherein the second electrode patterns located in the opposite U-shaped patterns defined by the two adjacent sensing electrode sets are connected to each other.

10. The touch panel as claimed in claim 1, further comprising a circuit board connected to the first pads and the second pads, and the circuit board has the connecting conductors.

11. The touch panel as claimed in claim 1, wherein a material of the first lines and the second lines comprises a transparent conductive material, a metal material, a metal mesh material, or a combination of at least two of the above.

12. The touch panel as claimed in claim 1, wherein the first lines and the second lines are substantially disposed in a coplanar configuration.

13. The touch panel as claimed in claim 1, wherein a material of the sensing electrode sets comprises a transparent conductive material, a metal material, a metal mesh material, or a combination of at least two of above.

14. The touch panel as claimed in claim 1, further comprising a decoration layer disposed at the periphery of the substrate.

15. The touch panel as claimed in claim 1, wherein the substrate is one of multiple substrates of a display.

16. The touch panel as claimed in claim 15, wherein the substrate is a color filter substrate of the display.

17. The touch panel as claimed in claim 15, wherein the display is an organic light emitting diode display, and the substrate is an encapsulation cover of the organic light emitting diode display.
